(19) United States
(12) Patent Application Publication
(10) Pub. No.: US 2008/0014739 A1
(43) Pub. Date: Jan. 17, 2008

(54) Silicon nitride/oxygen doped silicon carbide etch stop bi-layer for improved interconnect reliability

(75) Inventors: Laura M. Matz, Murphy, TX (US); Asad Haider, Plano, TX (US); Robert Kraft, Plano, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED

(21) Appl. No.: 11/475,924

(22) Filed: Jun. 28, 2006

(51) Int. Cl. H01L 21/4763; H01L 23/52; H01L 23/48; H01L 29/40

(52) U.S. Cl. 438/622; 257/758

(57) ABSTRACT

In accordance with the invention, there are semiconductor devices and methods for making semiconductor devices and film stacks in an integrated circuits. The method of making a semiconductor device can comprise forming a semiconductor structure comprising at least one copper interconnect, forming an etch stop bi-layer comprising a first layer and a second layer, wherein the first layer comprising silicon nitride is disposed over the semiconductor structure comprising at least one copper interconnect, and the second layer comprising silicon oxy-carbide is disposed over the first layer, and depositing a dielectric layer over the etch stop bi-layer.

### DESCRIPTION OF THE INVENTION

1. Field of the Invention

The subject matter of this invention relates to methods of fabricating semiconductor devices. More particularly, the subject matter of this invention relates to the methods of utilizing silicon nitride and silicon oxy-carbide etch stop bi-layer for improved interconnect reliability.

2. Background of the Invention

With the decrease in the size of integrated circuits, the need for copper and low k materials in the next generation interconnect structures is well recognized. Copper interconnect back-end-of line (BEOL) processing of silicon integrated circuits utilizes either single damascene or dual damascene processing. In damascene processing, metal is inlaid into patterned dielectric layers and chemical mechanical polishing (CMP) processes are used instead of metal etching. In damascene processes, generally, a barrier/hard mask/etch stop layer is stacked on top of the preceding interconnect copper layer to prevent copper migration and serve as a dry etch stop depending on the structure. Material for the barrier/etch stop layer must possess several properties such as being a good diffusion barrier, exhibit selectivity during interlevel dielectric etching, maintain electrical integrity through low leakage and good breakdown strength, and have a reasonable dielectric constant.

Problems arise with the scaling of BEOL interconnects from the 65 nm to 45 nm technology node as there is a greater impact of the etch stop film(s) on reliability and performance, specifically electromigration, electrical breakdown, and contribution to stack capacitance. Current BEOL processes utilizing etch stop bi-layer stack of silicon oxy-carbide over silicon carbo-nitride (SiCO/SiCN) do not meet all the reliability requirements. Current proposed solutions to the electromigration issues include employing a silane soak to improve copper adhesion prior to the etch stop dielectric film deposition. The silane soak process, however, may cause problems for the 45 nm technology node, as it runs the risk of increasing copper resistance.

Thus, there is a need to overcome these and other problems of the prior art and to provide methods for utilizing an etch stop bi-layer stack including silicon nitride and silicon oxy-carbide that improves reliability while reducing or maintaining stack capacitance.

### SUMMARY OF THE INVENTION

In accordance with the invention, there is a method of forming a film stack in an integrated circuit. The method can include forming a first etch stop layer of silicon nitride over a semiconductor structure containing at least one copper interconnect, forming a second etch stop layer of oxygen doped silicon carbide over the first etch stop layer, and depositing a dielectric layer over the second etch stop layer.

According to another embodiment of the present teachings, there is a method of making a semiconductor device. The method can include forming a semiconductor structure including at least one copper interconnect and forming an etch stop bi-layer including a first layer and a second layer, wherein the first layer including silicon nitride is disposed over the semiconductor structure including at least one copper interconnect, and the second layer including silicon oxy-carbide is disposed over the first layer. The method can also include depositing a dielectric layer over the etch stop bi-layer.

According to yet another exemplary embodiment, there is a semiconductor device. The semiconductor device can include a semiconductor structure including at least one copper interconnect, a first etch stop layer of silicon nitride disposed over the semiconductor structure including the at least one copper interconnect, a second etch stop layer of silicon oxy-carbide disposed over the first etch stop layer of silicon nitride layer, and a dielectric layer over the second etch stop layer.

Additional advantages of the embodiments will be set forth in part in the description which follows, and in part will be obvious from the description, or may be learned by practice of the invention. The advantages will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate embodiments of the invention and together with the description, serve to explain the principles of the invention.

### BRIEF DESCRIPTION OF THE DRAWINGS

FIG. 1 is a schematic illustration of an exemplary film stack in a semiconductor device in accordance with various embodiments of the present invention.

FIGS. 2A-2D depict schematic illustrations of an exemplary method for fabricating a semiconductor device according to various embodiments of the present invention.

FIG. 3 shows a graph comparing the electrical breakdown field of a conventional etch stop bi-layer with an exemplary etch stop bi-layer of the present invention.

### DESCRIPTION OF THE EMBODIMENTS

Reference will now be made in detail to the exemplary embodiments, examples of which are illustrated in the accompanying drawings. Wherever possible, the same reference numbers will be used throughout the drawings to refer to the same or like parts.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

The term “interconnect” is used interchangeably herein with terms including interconnect line, metal lines, trace, wire, conductor, signal path, and signaling medium. Interconnects are generally made of aluminum, copper or an alloy of copper and aluminum. Interconnects are conductors that provide signal paths for coupling or interconnecting electrical circuitry. Conductors other than the above mentioned metals include, for example, doped polysilicon, doped single crystal silicon, titanium, molybdenum, tungsten, and refractory metal silicides.

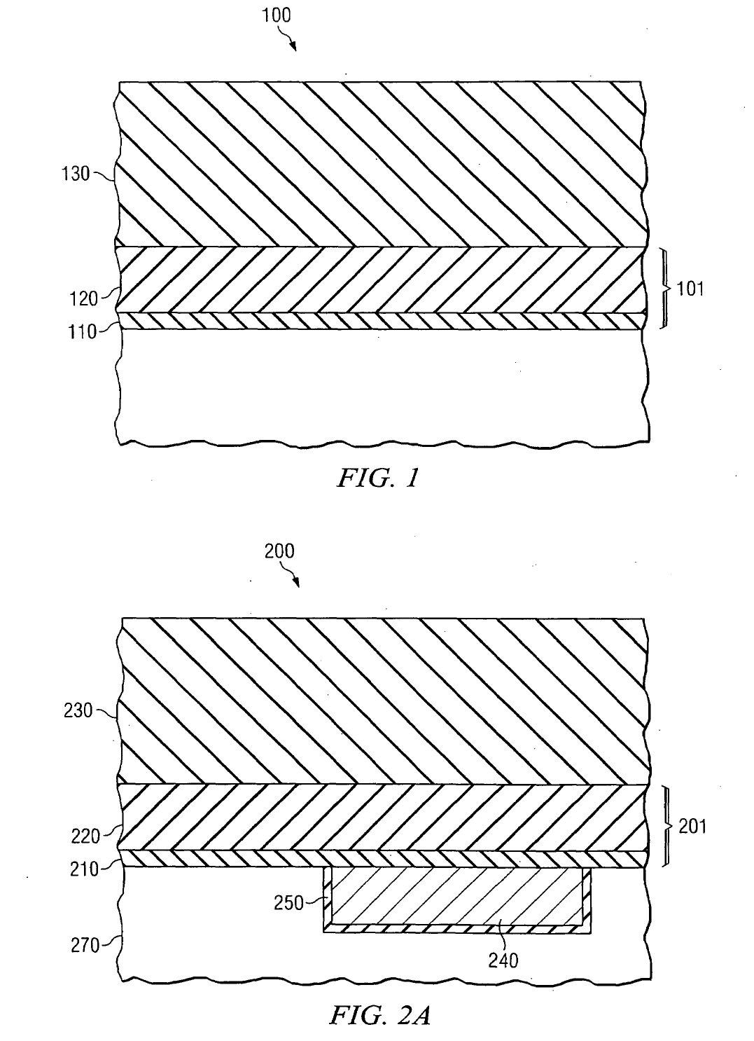

FIG. 1 is a schematic illustration of an exemplary film stack in a semiconductor device 100 according to the present teachings. The semiconductor device 100 can include an etch stop bi-layer stack 101 including a first etch stop layer 110 over a semiconductor structure containing at least one copper interconnect (not shown), a second etch stop layer 120 over the first etch stop layer 110, and a dielectric layer 130 over the second etch stop layer 120. According to various embodiments, the first etch stop layer 110 can be silicon nitride and the second etch stop layer 120 can be oxygen doped silicon carbide. In various embodiments, the dielectric layer 130 can be any interlevel dielectric material, such as, for example organo-silicate glass, fluorine-doped silicate glass, or tetraethyl orthosilicate.

One of ordinary skill in the art will understand that silicon nitride refers to a composition of the type SiₓN_{y}H_{z}, in both stoichiometric and solid solution ratio and silicon oxy-carbide refers to a composition of the type Si_{w}OₓC_{y}H_{z}, in both stoichiometric and solid solution ratio. According to various embodiments, copper in the semiconductor structure can be copper or an alloy of copper.

In various embodiments, the first etch stop layer 110 can have a thickness from about 10 Å to about 500 Å and the second etch stop layer 120 can have thickness from about 50 Å to about 500 Å. In some embodiments, the first etch stop layer 110 can have thickness from about 20 Å to about 50 Å and the second etch stop layer 120 can have thickness from about 100 Å to about 400 Å.

The dielectric constant, k of silicon oxy-carbide can be in the range of about 3.5 to about 5.0 and is lower than that of silicon nitride which can be in the range of about 6.0 to about 7.0. The actual dielectric constant of the silicon oxy-carbide layer and the silicon nitride layer depend on the deposition process parameters. The effective dielectric constant of the etch stop bi-layer stack 101 is the combined dielectric constant of the first etch stop layer 110 and the second etch stop layer 120. The effective dielectric constant can be adjusted by changing the process parameters during the deposition of the first etch stop layer 110 and the second etch stop layer 120 and also by adjusting the thickness ratio of the first etch stop layer 110 and the second etch stop layer 120. The effective dielectric constant of the etch stop bi-layer stack 101 can vary from about 4.1 to about 5.9. In the exemplary etch stop bi-layer stack 101, the effective dielectric constant can be around 4.7.

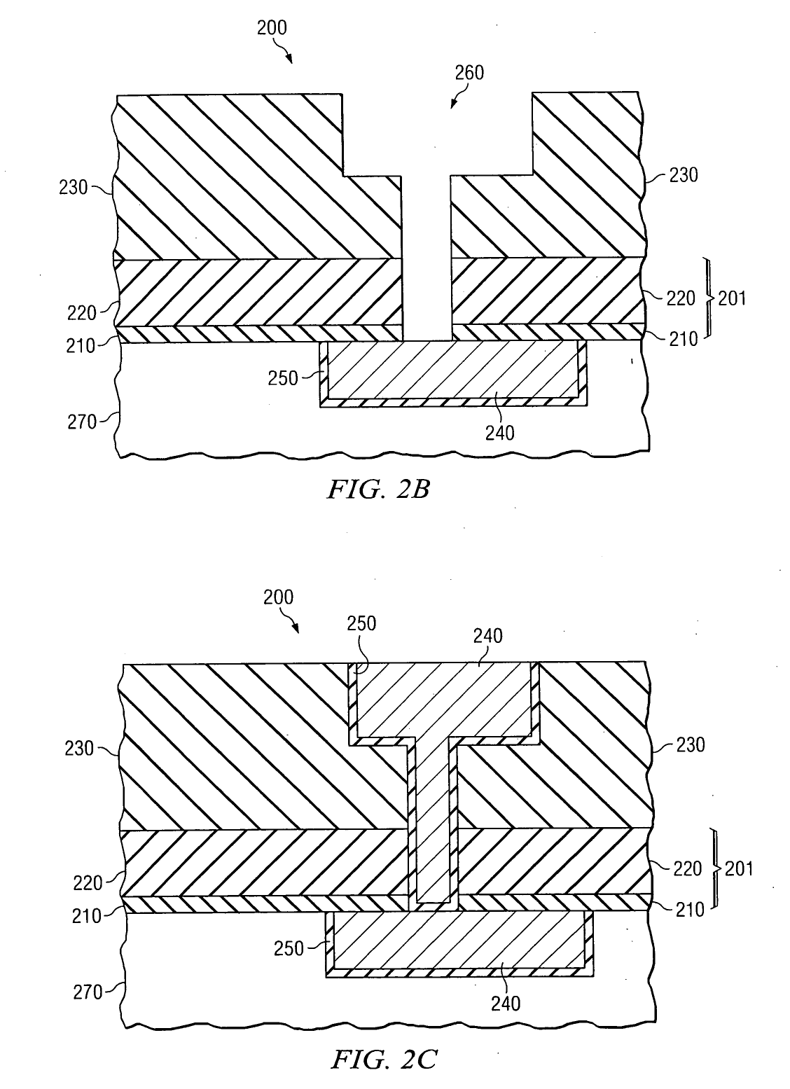

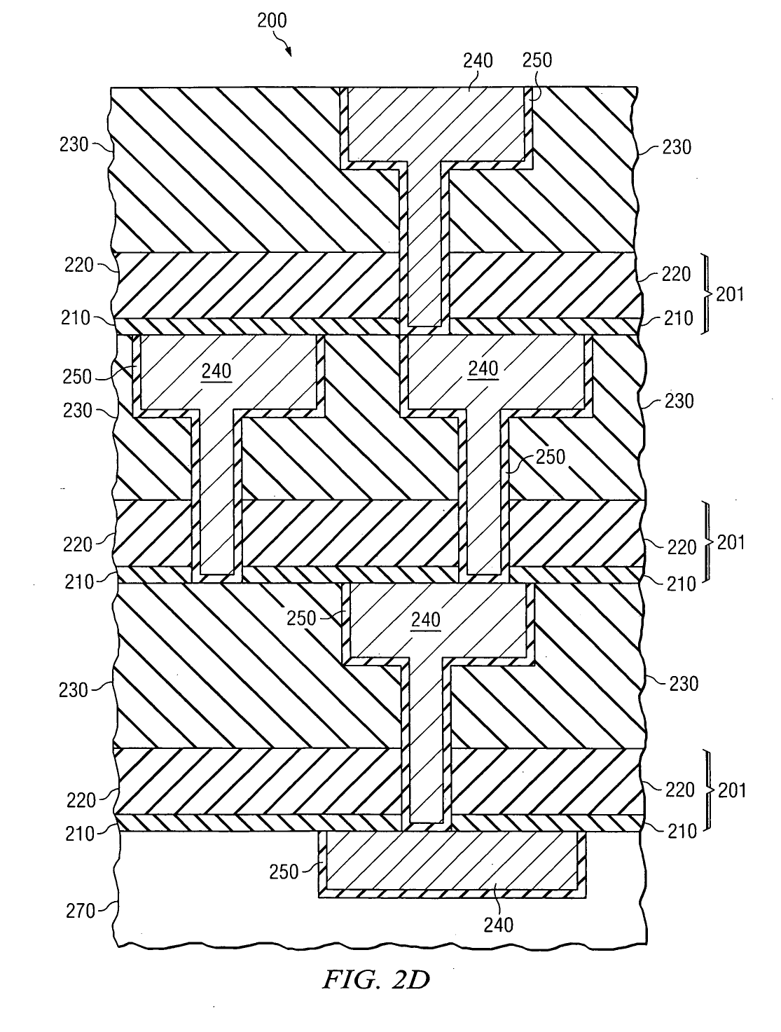

FIGS. 2A-2D depict schematic illustrations of an exemplary method for fabricating a semiconductor device 200 according to various embodiments of the present teachings. The method can include providing a semiconductor structure including at least one copper interconnect 240 on a semiconductor substrate 270. In some embodiments, the method can include providing a semiconductor structure including at least one copper interconnect 240 on a semiconductor substrate 270 and a metal barrier layer 250 on the bottom and sidewall of the copper interconnect 240. The method can further include forming a first etch stop layer 210 over the substrate 270 containing the at least one copper interconnect 240 and metal barrier layer 250, forming a second etch stop layer 220 over the first etch stop layer 210, and depositing a dielectric layer 230 over the second etch stop layer 220, as shown in FIG. 2A. In various embodiments, the dielectric layer 230 can be any interlevel dielectric material, such as, for example organo-silicate glass, fluorine-doped silicate glass, or tetraethyl orthosilicate.

In certain embodiments of the invention, the first etch stop layer 210 can be silicon nitride. One of ordinary skill in the art would know that there are various techniques for the deposition of silicon nitride including, but not limiting to CVD, LPCVD, PECVD, glow discharge, thermo catalytic (or hot wire) CVD, and atomic layer deposition (ALD). While not intending to be bound by any specific deposition method, in some embodiments; a mixture of gases such as silane, ammonia, and nitrous oxide can be used for the deposition of silicon nitride in a reactor. The silane flow rate can be in the range of about 50 sccm to about 500 sccm. The ammonia flow rate can be in the range of about 500 sccm to about 7000 sccm and nitrous oxide flow rate can be in the range of around 500 sccm to about 3000 sccm. The operating pressure of the reactor can be from around 3 Torr to around 12 Torr. The silicon nitride can be deposited at a reactor operating temperature ranging from about 350° C. to about 500° C. and typically high frequency RF power can range from about 0 to about 1000 W.

According to various embodiments, the second etch stop layer 220 can be oxygen doped silicon carbide. One of ordinary skill in the art would know that there are various methods for the deposition of silicon oxy-carbide including, but not limiting to CVD, LPCVD, PECVD, and ALD. While not intending to be bound by any specific deposition method, in certain embodiments, a mixture of gases including but not limiting to carbon dioxide, hydrogen, helium, tri-methyl silane (TMS), can be used in a reactor. The flow rate of carbon dioxide, hydrogen, tri-methyl silane, silane, and oxygen can be in the range of about 50 sccm to about 5000 sccm. The flow rate of helium can be in the range of about 100 sccm to about 10000 sccm. The silicon oxy-carbide can be deposited at a reactor operating temperature in the range of about 300° C. to about 400° C. and reactor pressure in the range of about 2.0 Torr to about 10 Torr. The power range for silicon oxy-carbide deposition can be from about 100 W to about 1000 W and low frequency RF power can be from about 50 W to about 400 W.

Turning back to the method of making a semiconductor device 200, the method can further include forming a damascene opening 260 to expose the underlying copper interconnect 240 as shown in FIG. 2B. One of ordinary skill in the art will understand that the damascene opening can be formed by etching including but is not limited to, chemical, plasma, physical (ion milling), and reactive ion etching. The method can also include depositing a layer of metal barrier 250 on the bottom and sidewall of the damascene opening 260 and filling the damascene opening 260 with copper or copper alloy 240 over the metal barrier layer 250 as shown in FIG. 2C. Copper filling can be done by electrochemical plating, electroless plating, or chemical vapor deposition. One of ordinary skill in the art will understand that the copper fill can be accompanied by planarization such as chemical mechanical polishing to remove excess copper or copper alloy from the dielectric layer 230.

The method can further include forming another etch stop bi-layer stack 201 over the dielectric layer 230 containing the at least one copper interconnect 240, depositing another dielectric layer 230 over the dielectric stack 201, forming a damascene opening, filling the damascene opening with copper or copper alloy and repeating the process as many times as required as shown in FIG. 2D.

In various embodiments, the exemplary etch stop bi-layer stack 101, as shown in FIG. 1, can be compared to a conventional etch stop bi-layer stack with respect to dielectric constant, etch selectivity, electrical breakdown, electromigration, deposition/clean cost, by fabricating for example, comb-serpentine structures. In certain embodiments, the conventional etch stop bi-layer stack can include a first layer of about 200 Å thick silicon carbo-nitride over a semiconductor structure containing at least one copper interconnect, a second layer of about 400 Å thick silicon oxy-carbide over the first layer of silicon carbo-nitride, and about 500 Å thick layer of ultra low k organo silicate glass (ULK-OSG) over the second layer of silicon oxy-carbide. In some embodiments, the exemplary etch stop bi-layer can have the first etch stop layer 110 formed of about 50 Å thick layer of silicon nitride, the second etch stop layer 120 formed of about 400 Å thick layer of silicon oxy-carbide over the first etch stop layer 110, and the dielectric layer 130 formed of an approximately 650 Å thick layer of ultra low-k organo silicate glass (ULK-OSG) 130 over the second etch stop layer 120.

According to the various embodiments, the exemplary etch stop bi-layer stack 101 of the present teachings either meets or exceeds the reliability requirements for the 45 nm etch stop films. In certain embodiments, the use of four times thinner first etch stop layer 110 in the exemplary etch stop bi-layer stack 101 as compared to the first etch stop layer of the conventional etch stop bi-layer can result in about a 9% reduction in the effective dielectric constant of the etch stop bi-layer stack 101. The about 9% reduction of the effective dielectric constant can result in about a 9% reduction in line to line capacitance. In other embodiments, the electrical breakdown field of the exemplary etch stop bi-layer stack 101 (8.0 MV/cm) can be about 12% higher than the conventional etch stop bi-layer stack (7.15 MV/cm). Furthermore in some embodiments, though the electromigration t₅₀ of the exemplary etch stop bi-layer stack 101 does not differ in value from that of the conventional etch stop bi-layer, there can be, however, a 27% reduction in sigma, where t₅₀ is the time to failure for 50% of the distribution and sigma is the standard deviation of the fail distribution. The reduction of sigma indicates the possibility for longer lifetime on a higher percentage of semiconductor devices.

In certain embodiments, the etch selectivity to the organo silicate glass (ULK-OSG) etch of the exemplary etch stop bi-layer 101 of the present teachings can be the same as that of the conventional etch stop bi-layer. The reason for no difference in the etch selectivity is due to the fact that the second etch stop layer of both the conventional etch stop bi-layer stack and the exemplary etch stop bi-layer stack 101 include a 400 Å thick layer of silicon oxy-carbide. Since, silicon oxycarbide layer is adjacent to the organo silicate glass layer (ULK-OSG), the etch selectivity to ULK-OSG of the exemplary and the conventional etch stop bi-layer can be the same. In some embodiments, the etch stop etch thickness of the exemplary etch stop bi-layer stack 101 can be lower than that of the conventional etch stop bi-layer stack. The reason for the lower etch stop etch thickness of the exemplary etch stop bi-layer stack 101 is probably because the thickness of silicon nitride (about 50 Å) which is the first etch stop layer 110 of the exemplary etch stop bi-layer stack 101 is about one fourth the thickness of corresponding layer of silicon carbo-nitride (about 200 Å), which is the first etch stop layer of the conventional etch stop bi-layer. Silicon nitride is considered to be a better dielectric barrier than the silicon carbon-nitride and therefore the thickness of the silicon nitride, the first etch stop bi-layer 110 of the exemplary etch stop bi-layer stack 101 can be decreased four times without any adverse effect to the reliability.

Photo-poisoning of photoresist is considered to be caused by a diffusion of reactive nitrogeneous species such as amine out of silicon and nitrogen containing layer and into the photo-resist layer. A layer of silicon oxy-carbide between the photoresist and silicon and nitrogen containing layer is known to prevent photo-poisoning. In certain embodiments, both the exemplary and the conventional etch stop bi-layer showed no significant difference in the photo-poisoning effect because the thickness of the silicon oxy-carbide is the same in the two cases. In other embodiments, about 28% reduction in deposition/cleaning cost can be observed in the exemplary etch stop bi-layer stack 101 as compared to the conventional etch stop bi-layer stack due to lower overall etch stop thickness with the silicon nitride thickness reduction.

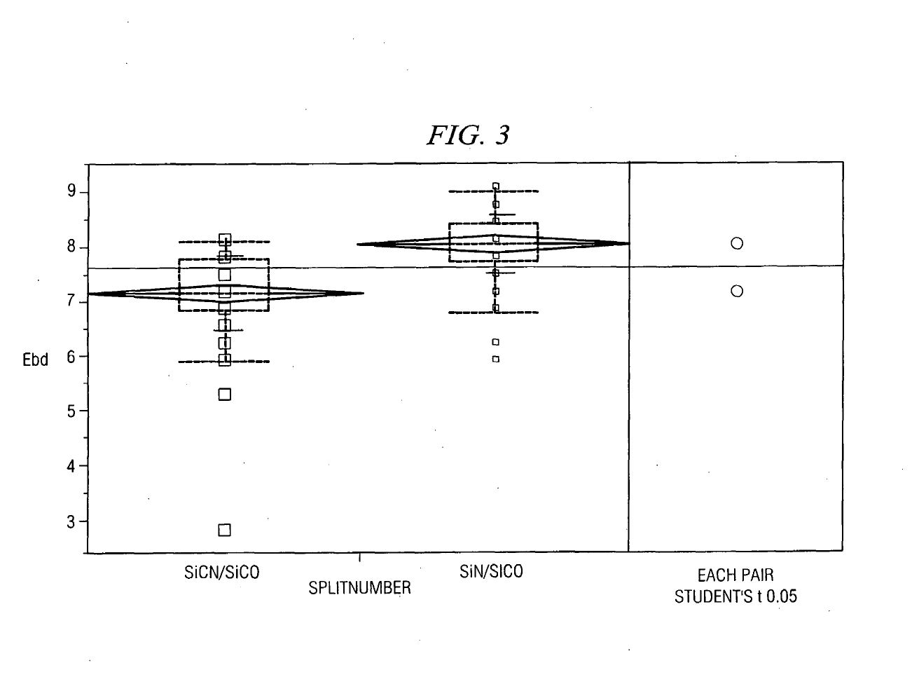

FIG. 3 shows a comparison of the electrical breakdown field of a conventional etch stop bi-layer stack with an exemplary etch stop bi-layer stack 101. The measurements were done using a comb-serpentine test structure. As shown in FIG. 3, the mean breakdown field of the exemplary etch stop bi-layer stack (8.02 MV/cm) is about 12% higher than the mean breakdown field of the conventional etch stop bi-layer stack (7.15 MV/cm).

According to various embodiments, the exemplary etch stop bi-layer 101 including a layer of silicon oxy-carbide 120 over a layer of silicon nitride 110 can provide numerous advantages such as improvement in electrical breakdown field, no impact to sheet resistance due to absence of silane step needed previously to improve adhesion to copper, improvement in electromigration, and/or a reduction in cleaning costs. Further, shorter etch stop times can help with ultra low k preservation and also center-to-edge non-uniformity requirement for over-etch.

According to various embodiments, there is a method of forming a film stack 101 in an integrated circuit. The method can include forming a first etch stop layer 110 of silicon nitride over a semiconductor structure containing at least one copper interconnect, forming a second etch stop layer 120 of oxygen doped silicon carbide over the first etch stop layer 110; and depositing a dielectric layer 130 over the second etch stop layer 120.

In certain embodiments, a semiconductor device 200 can include a semiconductor structure 270 including at least one copper interconnect 240. The semiconductor device 200 can also include a first etch stop layer 210 of silicon nitride disposed over the semiconductor structure 270, a second etch stop layer 220 of silicon oxy-carbide disposed over the first etch stop layer 210 of silicon nitride layer, and a dielectric layer 230 over the second etch stop layer 220.

While not intending to be bound to any particular theory, it is believed that the exemplary etch stop bi-layer meet or exceed the requirements of the 45 nm etch stop films because the first etch stop layer including silicon nitride prevents the formation of copper oxides and the second etch stop layer including silicon oxy-carbide prevents the diffusion of nitrogeneous species.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations. as may be desired and advantageous for any given or particular function. Furthermore, to the extent that the terms “including”, ”includes”, “having”, “has”, “with”, or variants thereof are used in either the detailed description and the claims, such terms are intended to be inclusive in a manner similar to the term “comprising.”

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of forming a film stack in an integrated circuit comprising:
forming a first etch stop layer of silicon nitride over a semiconductor structure containing at least one copper interconnect;
forming a second etch stop layer of oxygen doped silicon carbide over the first etch stop layer; and
depositing a dielectric layer over the second etch stop layer.

2. The method of claim 1, wherein forming a first etch stop layer of silicon nitride comprises depositing a layer of silicon nitride that has thickness between approximately 10 angstrom to approximately 100 angstrom.

3. The method of claim 1, wherein forming a second etch stop layer of oxygen doped silicon carbide comprises depositing a layer of oxygen doped silicon carbide that has thickness between approximately 100 angstrom to approximately 600 angstrom.

4. The method of claim 1, wherein forming a first etch stop layer of silicon nitride comprises depositing a layer of silicon nitride that has dielectric constant between approximately 6.0 to approximately 7.0.

5. The method of claim 1, wherein forming a second etch stop layer of oxygen doped silicon carbide comprises depositing a layer of oxygen doped silicon carbide that has dielectric constant between approximately 3.5 to approximately 5.0.

6. The method of claim 1, wherein the effective dielectric constant of the first etch stop layer and the second etch stop layer is less than approximately 5.0.

7. The method of claim 1, wherein the dielectric layer comprises at least one of an organo silicate glass, fluorine-doped silicate glass, and tetraethyl orthosilicate.

8. A method of making a semiconductor device, the method comprising:
forming a semiconductor structure comprising at least one copper interconnect;
forming an etch stop bi-layer comprising a first layer and a second layer, wherein the first layer comprising silicon nitride is disposed over the semiconductor structure comprising at least one copper interconnect, and the second layer comprising silicon oxy-carbide is disposed over the, first layer; and
depositing a dielectric layer over the etch stop bi-layer.

9. The method of claim 8, wherein forming the first layer of the etch stop bi-layer comprises depositing a layer of silicon nitride that has thickness between approximately 10 angstrom to approximately 100 angstrom.

10. The method of claim 8, wherein forming the second layer of the etch stop bi-layer comprises depositing a layer of silicon oxy-carbide that has thickness between approximately 100 angstrom to approximately 600 angstrom.

11. The method of claim 8, wherein forming the first layer of the etch stop bi-layer comprises depositing a layer of silicon nitride that has dielectric constant between approximately 6.0 to approximately 7.0.

12. The method of claim 8, wherein forming the second layer of the etch stop bi-layer comprises depositing a layer of silicon oxy-carbide that has dielectric constant between approximately 3.5 to approximately 5.0.

13. The method of claim 8, wherein the effective dielectric constant of the etch stop bi-layer is less than approximately 5.0.

14. The method of claim 8, wherein the dielectric layer comprises an ultra low k interlevel dielectric.

15. A semiconductor device comprising:
a semiconductor structure comprising at least one copper interconnect;
a first etch stop layer of silicon nitride disposed over the semiconductor structure comprising the at least one copper interconnect;
a second etch stop layer of silicon oxy-carbide disposed over the first etch stop layer of silicon nitride layer; and
a dielectric layer over the second etch stop layer.

16. The semiconductor device of claim 15, wherein the first etch stop layer of silicon nitride has a thickness less than approximately 100 angstrom.

17. The semiconductor device of claim 15, wherein the second etch stop layer of silicon oxy-carbide has a thickness less than approximately 600 angstrom.

18. The semiconductor device of claim 15, wherein the first etch stop layer of silicon nitride has dielectric constant less than approximately 7.0.

19. The semiconductor device of claim 15, wherein the second etch stop layer of silicon oxy-carbide has dielectric constant less than approximately 5.0.

20. The semiconductor device of claim 15, wherein the effective dielectric constant of the first etch stop layer and the second etch stop layer is less than approximately 5.0.

21. The semiconductor device of claim 15, wherein third layer of dielectric comprises at least one of an organo silicate glass, fluorine-doped silicate glass, and tetraethyl orthosilicate.
